(19) United States
(12) Patent Application Publication
(10) Pub. No.: US 2026/0238245 A1
(43) Pub. Date: Aug. 13, 2026

(54) RADIO SYSTEM

(71) Applicant: GM GLOBAL TECHNOLOGY OPERATIONS LLC, Detroit, MI (US)

(72) Inventors: Uriel Z. Odes, Givaat Shmuel (IL); Yossi Diller, PetahTikva (IL)

(73) Assignee: GM GLOBAL TECHNOLOGY OPERATIONS LLC, Detroit, MI (US)

(21) Appl. No.: 19/049,216

(22) Filed: Feb. 10, 2025

(51) Int. Cl. H04B 1/40; H03F 3/21; H04B 1/00

(52) U.S. Cl. CPC H04B 1/40; H03F 3/211; H04B 1/0064; H03F 2200/451

(57) ABSTRACT

A radio system includes a first source of first radio signals, the first radio signals being in a first frequency range, the first source including a first amplifier. Additionally, the radio system includes a second source of second radio signals, the second radio signals being in a second frequency range distinct from the first frequency range. The radio system enables use of one coaxial cable to pass the first radio signals and the second radio signals to radio receivers and to pass direct current (“DC”) power for powering the first and second amplifiers.

This disclosure is in the field of radio systems.

Vehicles may be equipped with radio systems operating with radio signals received in multiple frequency bands. In order to provide favorable performance of a radio system, coaxial cables may be used to route the radio signals from the antennas that receive the signals to the audio receivers that decode/demodulate the signals. Where a vehicle's radio system operates to receive multiple radio signals in multiple frequency bands, the vehicle may include multiple coaxial cables. Because coaxial cables are complex electrical components that add weight and packaging complexity to the vehicle, reducing the number of coaxial cables needed in a vehicle can be advantageous.

### SUMMARY

A radio system includes a first source of first radio signals, the first radio signals being in a first frequency range, the first source including a first amplifier with a first amplifier output. Additionally, the radio system includes a second source of second radio signals, the second radio signals being in a second frequency range, the second frequency range distinct from the first frequency range, the second source including a second amplifier with a second amplifier output. Further, the radio system includes a first filter adapted to substantially reject the second frequency range, the first filter having a first filter input and a first filter output, the first filter input coupled to the first amplifier output. In addition, the radio system includes a second filter adapted to substantially reject the first frequency range, the second filter having a second filter input and a second filter output, the second filter input coupled to the second amplifier output. Further, the radio system includes a first bias-tee circuit having a first direct current (“DC”) terminal, a first radiofrequency (“RF”) terminal, and a first DC+RF terminal, the first RF terminal coupled to the first filter output and to the second filter output, and a second bias-tee circuit having a second DC terminal, a second RF terminal, and a second DC+RF terminal. In addition, the radio system includes a DC power supply coupled to supply power to the second DC terminal. In addition, the radio system includes a conductor coupling the first DC+RF terminal and the second DC+RF terminal, the conductor carrying the first radio signals for reception by a first receiver, the second radio signals for reception by a second receiver, and DC power from the DC power supply to power the first amplifier and the second amplifier. The first filter may be a low-pass filter adapted to substantially reject the second frequency range, and it may more particularly be a Butterworth filter. The second filter may be a high-pass filter. Adapted to substantially reject the first frequency range. The first filter may include electrical components in 0805, 0603, or 0402 packages. The first filter may include at least some electrical components having higher quality factors than at least some components included in the second filter.

In the radio system, the first radio signals may be amplitude modulated/frequency modulated (“AM/FM”) signals. The first radio signals may also be FM signals. The second radio signals may be satellite radio signals. The satellite radio signals may be Sirius XM (“SXM”) signals.

The radio system may also include a third filter having a third filter input and a third filter output and a fourth filter having a fourth filter input and a fourth filter output. The third filter input may be coupled to the second RF terminal, the fourth filter input may be coupled to the second RF terminal, the third filter output may be coupled to the first receiver, and the fourth filter output may be coupled to the second receiver. The third filter may be adapted to substantially reject the second frequency range, and the fourth filter may be adapted to substantially reject the first frequency range.

The radio system may also include a first inductive-capacitive (“L-C”) matching circuit disposed between the first filter output and the first RF terminal and between the second filter output and the first RF terminal. The radio system may further include a second L-C matching circuit disposed between the second RF terminal and the third filter input and between the second RF terminal and the fourth filter input.

Further, the radio system may contain a voltage splitter having a voltage splitter input coupled to receive power from the first DC terminal, a first voltage splitter output coupled to provide DC power to the first amplifier, and a second voltage splitter output coupled to provide DC power to the second amplifier. The voltage splitter output may have a voltage that is different than a voltage of the second voltage splitter output.

A vehicle may contain a radio system disclosed herein.

The above summary does not represent every embodiment or every aspect of this disclosure. The above-noted features and advantages of the present disclosure, as well as other possible features and advantages, will be readily apparent from the following detailed description of the embodiments and best modes for carrying out the disclosure when taken in connection with the accompanying drawings and appended claims. Moreover, this disclosure expressly includes combinations and sub-combinations of the elements and features presented above and below.

### BRIEF DESCRIPTION OF THE DRAWINGS

FIG. 1 illustrates a vehicle with a radio system.

FIG. 2 is a block diagram of a radio system of the vehicle of FIG. 1.

FIG. 3 illustrates the bias-tee circuit of FIG. 2.

FIG. 4 is a block diagram of the voltage splitter of FIG. 2.

FIG. 5 illustrates circuitry of the filters and matching circuit of FIG. 2.

### DETAILED DESCRIPTION

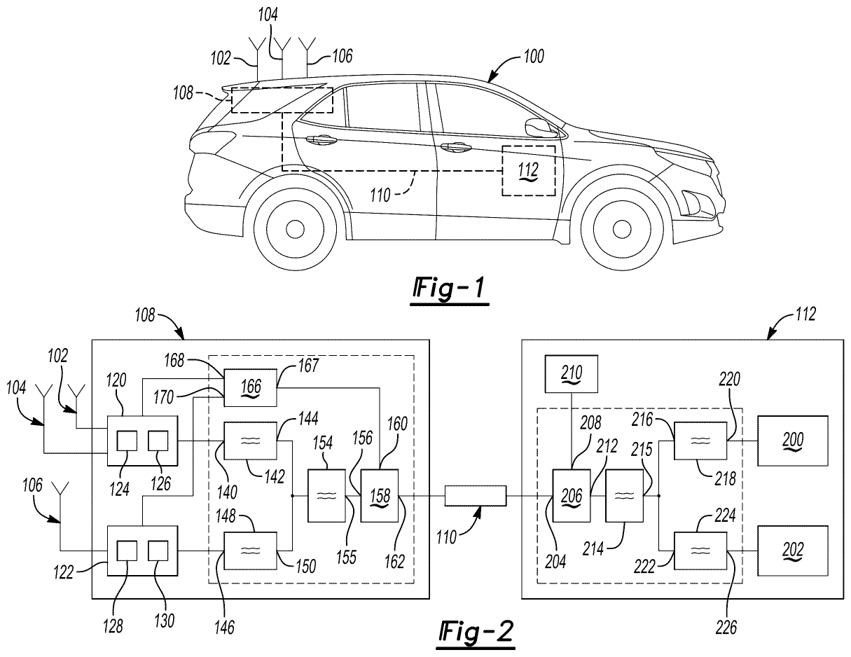

Refer first to FIG. 1. Illustrated there is a vehicle 100. Vehicle 100 may be any type of style of vehicle, such as a car, truck, van, sport-utility vehicle, motorcycle, boat, or aircraft. Vehicle 100 may be equipped with a radio system that is adapted to receive radio signals in a variety of bands. Such bands may include amplitude modulation (“AM”), which may operate at frequencies between about 540 kilohertz (“KHz”) and about 1700 KHz; frequency modulation (“FM”), which may operate at frequencies between about 88 megahertz (“MHz”) and about 108 MHz; and satellite radio, which may operate at frequencies in the gigahertz (“GHz”) range (that is, they are “gigahertz radio signals”) and which may be in a range between about 2 GHz and about 4 GHz. One satellite radio service provider operates under the brand name Sirius XM (which may be referred to hereinafter in this disclosure as “SXM”), which operates in a range of 2.320 GHz to 2.345 GHz.

Vehicle 100 may have multiple antennas for receiving the signals of the various radio bands which the radio system of vehicle 100 may receive. For instance, antenna 102 may be an AM radio antenna, suited by, for instance, its geometry for reception of AM radio signals. Further, antenna 104 may be an FM radio antenna, suited particularly for reception of FM radio signals. Additionally, antenna 106 may be a satellite radio antenna, suited particularly for reception of satellite radio signals. Antenna 102, antenna 104, and antenna 106 may feed to a tuner antenna module 108. Tuner antenna module 108 may be located near antenna 102, antenna 104, and antenna 106, near the roof of vehicle 100 and possibly in the ceiling of vehicle 100. Proximity to the antennas to tuner antenna module 108 allows the signals from the antennas to be locally filtered and amplified. This local processing may help provide a strong, low-noise signal for routing of the signals through vehicle 100 while maintaining a favorably-high signal-to-noise ratio. One or more of the antennas may also be combined into multi-band antennas that are adapted for receiving, say, AM and FM. Further, the signals from antenna 102 (the AM antenna) and from antenna 104 (the FM antenna) may be combined to provide a combined AM/FM signal. That combined AM/FM signal may have a frequency range that represents the concatenation of the frequency ranges of AM and FM, namely about 540 KHz (on the low end) to about 108 MHz (on the high end).

In view of the foregoing discussion, the AM/FM signals and the SXM signals may be viewed as being in distinct (i.e., not overlapping) frequency ranges. The AM signals and the SXM signals may likewise be viewed as being in distinct frequency ranges as may be the FM signals and the SXM signals.

The signals from antenna 102, antenna 104, and antenna 106 that leave tuner antenna module 108 may be routed by a conductor 110, such as a coaxial cable, to a central control unit 112. Central control unit 112 may contain radio receiver units, modules, or circuitry for decoding the AM, FM, and satellite radio signals for use by the audio system in vehicle 100, e.g., for playing the decoded/demodulated content through audio loudspeakers in vehicle 100. Central control unit 112 may also contain electronics for performing additional and various functions within vehicle 100. Conductor 110 may have a length suitable for connecting tuner antenna module 108 with central control unit 112. Depending upon the geometry of vehicle 100, that length may be in the range of 2.5 to 5 meters.

Refer now to FIG. 2. Tuner antenna module 108 may include an AM/FM front end module (“FEM”) 120 and an SXM front end module (“FEM”) 122. AM/FM FEM 120 may include a filter 124. Filter 124 may be adapted to reject out-of-band noise in the AM/FM signals. AM/FM FEM 120 may also include an amplifier 126. Amplifier 126 amplifies the AM/FM signal to help provide a strong, low-noise signal for routing through vehicle 100 while maintaining a favorably-high signal-to-noise ratio. Amplifier 126 may be a so-called low noise amplifier (“LNA”) that is particularly adapted to amplifying signals in environments where noise is especially disadvantageous. In general, a low-noise amplifier is an electronic component that amplifies a very low-power signal without significantly degrading its signal-to-noise ratio. Amplifier 126 may also be executed by multiple amplifiers arranged in series.

AM/FM FEM 120 may also be replaced by an FEM that only includes FM or by an FEM that only includes AM.

SXM FEM 122 may include a filter 128, which may be adapted to reject out-of-band noise in the SXM signals. SXM FEM 122 may also include an amplifier 130. Amplifier 130 amplifies the SXM signals to help provide a strong, low-noise signal for routing through vehicle 100 while maintaining a favorably-high signal-to-noise ratio. Amplifier 130 may be a so-called low noise amplifier (“LNA”) that is particularly adapted to amplifying signals in environments where noise is especially disadvantageous. In general, a low-noise amplifier is an electronic component that amplifies a very low-power signal without significantly degrading its signal-to-noise ratio. Amplifier 130 may also be executed by multiple amplifiers arranged in series.

The FEMs may be viewed as sources of the respective radio signals that are output from the FEMs.

The output of AM/FM FEM 120 may be coupled to the input 140 of a filter 142; filter 142 may also have an output 144. The output of SXM FEM 122 may be coupled to input 146 of a filter 148; filter 148 may also have an output 150.

Output 144 of filter 142 and output 150 of filter 148 may be coupled to a matching circuit 154 with an output 155. Output 155 of matching circuit 154 may in turn be coupled to the RF terminal 156 of a bias-tee circuit 158.

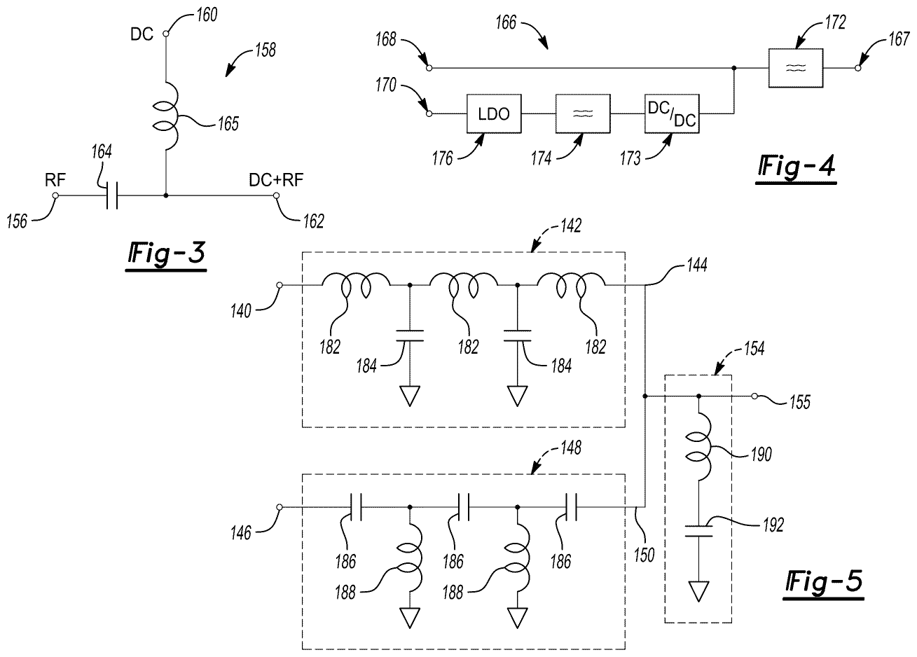

Refer now additionally to FIG. 3 for additional detail of bias-tee circuit 158. Bias-tee circuit 158 may be circuitry that may have, as discussed, an RF terminal 156. Bias-tee circuit 158 may also have a DC terminal 160. Further, bias-tee circuit 158 may have a DC+RF terminal 162. Bias-tee circuit 158 may also include capacitor 164 and inductor 165. Capacitor 164 may be a combination of a plurality of capacitors (say, in parallel), and inductor 165 may be a combination of a plurality of inductors (say, in series), to be effective at multiple frequencies. Bias-tee circuit 158 may be designed, and capacitor 164 and inductor 165 may be sized, to allow DC biasing of an RF signal.

Refer again to FIG. 2. DC terminal 160 of bias-tee circuit 158 may be coupled to a voltage splitter 166. Voltage splitter 166 may provide DC power via output 168 to power amplifier 126 and via output 170 to power amplifier 130. Each of amplifier 126 and amplifier 130 may be active amplifiers and therefore may need sources of DC power.

Refer now additionally to FIG. 4 for additional detail of voltage splitter 166. Voltage splitter 166 may be adapted to provide two different output voltages to output 168 and output 170. Voltage splitter 166 may include a radiofrequency filter 172. The output of radiofrequency filter 172 may be provided directly to output of voltage splitter 166, in the event that the relevant amplifier, here amplifier 126, operates on the voltage provided at input 167. The output of radiofrequency filter 172 may also be provided to a DC/DC converter 173, which may be of a “buck” topology, which may be useful for voltage reduction. The output of DC/DC converter 173 may be provided to an additional radiofrequency filter 174 to filter out electrical noise that may have been introduced by DC/DC converter 173. The output of radiofrequency filter 174 may be provided to a low-dropout (“LDO”) voltage regulator 176, and the output of LDO voltage regulator 176 provided to output 170 of voltage splitter 166. Note that the voltage at output 170 of voltage splitter 166 may be less than the voltage at output 168 of voltage splitter 166. DC/DC converter 173 may be omitted and simply LDO voltage regulator 176 used if the magnitude of voltage reduction needed is limited.

If amplifier 126 and amplifier 130 are powered by equal DC voltages, voltage splitter 166 may be omitted; “DC” terminal 160 of bias-tee circuit 158 may in that case be coupled to power both amplifier 126 and amplifier 130, possibly via a radiofrequency filter if needed.

DC+RF terminal 162 of bias-tee circuit 158 may be coupled to conductor 110. Conductor 110 may be a coaxial cable having an internal signal conductor surrounded by an electrical-noise-protective shield.

Refer now additionally to FIG. 5. Filter 142 may be a low-pass filter. Filter 142 may additionally be a Butterworth filter comprised of inductors 182 and capacitors 184. As a low-pass filter, filter 142 may be adapted to pass the relatively lower frequencies of AM/FM but reject, substantially reject, or filter out the relatively higher frequencies of SXM. Inductors 182 and capacitors 184 may be selected to have a desirable frequency breakpoint for filter 142. Filter 142 may be designed to have as simple or complex a topology as appropriate for providing the filtering characteristics (frequency breakpoint, steepness of rolloff of its frequency response) desired to pass the AM/FM frequencies but suitably reject or substantially reject the SXM frequencies. A simpler topology may provide the benefit of fewer components and lower electrical losses. Given the relatively large frequency separation between the AM/FM bands and the SXM band, a relatively-simple Butterworth filter topology with a modest slope in the rolloff of its frequency response may be suitable for filter 142.

The frequency breakpoint of filter 142, which may also sometimes be referred to as its “cut-off” or “knee” frequency, may be selected to be above the upper end of the AM/FM frequency range (say, above 108 MHz) but below the lower end of the satellite radio frequency range (say, below 2 GHz or 2.3 GHz). The frequency breakpoint may be the frequency at which filter 142 has a voltage gain of √2/2≈0.707 or—3 dB. The frequency breakpoint may be a boundary of a passband of filter 142 (below the frequency breakpoint, where filter 142 may be considered to largely pass frequency components applied to filter 142) and a stop band of filter 142 (above the frequency breakpoint, where filter 142 may be considered to largely stop, block, or filter out frequency components applied to filter 142).

Filter 148 may be a high-pass filter. Filter 148 may additionally be a Butterworth filter comprising capacitors 186 and inductors 188. As a high-pass filter, filter 148 may be adapted to pass the relatively higher frequencies of SXM but reject, substantially reject or filter out the relatively lower frequencies of AM/FM. Capacitors 186 and inductors 188 may be selected to have a desirable frequency breakpoint for filter 148. Filter 148 may be designed to have as simple or complex a topology as appropriate for providing the filtering characteristics (frequency breakpoint, steepness of rolloff) desired to pass the SXM frequencies but suitably reject the AM/FM frequencies. A simpler topology may provide the benefit of fewer components and lower electrical losses. Given the relatively large frequency separation between the AM/FM bands and the SXM band, a relatively-simple Butterworth filter topology with a modest slope in the rolloff of its frequency response may be suitable for filter 148.

The frequency breakpoint of filter 148 may be selected to be above the upper end of the AM/FM frequency range (say, above 108 MHz) but below the lower end of the satellite radio frequency range (say, below 2 GHz or 2.3 GHz). The frequency breakpoint may be the frequency at which filter 148 has a voltage gain of √2/2≈0.707 or—3 dB. The frequency breakpoint may be a boundary of a passband of filter 148 (above the frequency breakpoint, where filter 148 may be considered to largely pass frequency components of the signal applied to filter 148) and a stop band of filter 148 (below the frequency breakpoint, where filter 148 may be considered to largely stop, block, or filter out frequency components of the signal applied to filter 148).

Filter 148 may comprise relatively small capacitors 186 and inductors 188. They may be chip based or surface mounted and may be in so-called “0201” packages or may be printed components. Filter 142, which may include larger-value inductors and capacitors due to the lower frequency of the AM/FM signals relative to the SXM signals, may employ high-Q (that is, “high quality factor”) inductors and capacitors with reduced energy losses for better efficiency. High-Q components may be larger than other components and their use in the present system may otherwise be counterintuitive, but they may be appropriate for use in the lower-frequency environment of filter 142, Inductors 182 and capacitors 184 may in so-called “0805” packages, “0603” packages, or “0402” packages. Some or all of inductors 182 may be of higher Q-factor than some or all of inductors 188. Further, some or all of capacitors 184 may be of higher Q-factor than some or all of capacitors 186.

A “0805” package may be about 2.0 mm (length) by 1.2 mm (width). A “0603” package may be about 1.55 mm (length) by 0.85 mm (width). A “0402” package may be about 1.0 mm (length) by 0.5 mm (width). A “0201” package may be about 0.6 mm (length) by 0.3 mm (width).

Matching circuit 154 may be a circuit comprising an inductor and capacitor (that is, an “L-C” circuit) adapted as a matching filter or tuning filter, with inductor 190 and capacitor 192 (or combinations of inductors and capacitors) selected as appropriate to tune the circuit. Matching circuit 154 may be designed to reduce signal reflections. Matching circuit 154 may have an output 155. Matching circuit 154 may use larger “0805”, “0603” or “0402” capacitors and inductors and may be high-Q or relatively high-Q components.

Refer again to FIG. 2. Central control unit 112 includes an AM/FM receiver module 200, which is adapted to decode/demodulate the AM/FM signals that were received by antenna 104 and antenna 106 and provide the decoded/demodulated signals as e.g., audible output from the audio system of vehicle 100. Central control unit 112 also includes an SXM receiver module 202, which is adapted to decode/demodulate the SXM signals that were received by antenna 102 and provide the decoded/demodulated signals as e.g., audible output from the audio system of vehicle 100.

It should be noted that the radio system described herein may be architected in various alternative ways that do not depart from the spirit of this disclosure. For instance, AM/FM receiver module 200 may be integrated with SXM receiver module 202. Or, AM/FM receiver module 200 may include separate modules for AM reception and FM reception. Therefore, when reference is made in this disclosure to an “SXM receiver”, such reference should be construed to mean a device that is adapted to decode/demodulate SXM signals, whether such receiver is standalone or is integrated with other electronics. Likewise for references to “AM/FM receiver”, “AM receiver”, and “FM receiver”.

Conductor 110 may be coupled to an DC+RF terminal 204 of bias-tee circuit 206. (It may be noted that the topology of bias-tee circuit 206 may be similar to or the same as the topology of bias-tee circuit 158.) DC terminal 208 of bias-tee circuit 206 may be coupled to a DC power supply 210. DC power supply 210 may, for instance, be a 12 volt power supply, a 5 volt power supply, an 8.5 volt power supply, or a DC power supply of another suitable voltage for powering amplifier 126 and amplifier 130.

RF terminal 212 of bias-tee circuit 206 may be coupled to matching circuit 214. Matching circuit 214 may be of similar topology to matching circuit 154 and may be designed with similar or the same design considerations as matching circuit 154.

Output 215 of matching circuit 214 may be coupled to the input 216 of a filter 218; filter 218 may also have an output 220. Filter 218 may be a low-pass filter, designed to suitably pass the relatively-lower AM/FM frequencies and suitably reject, substantially reject or filter out the relatively-higher SXM frequencies. Filter 218 may be similar to or identical with filter 142, and similar design considerations may apply. Filter 218 may be a Butterworth filter, a relatively-simple filter that may be employed given the relatively-large separation between the AM/FM frequency bands and the SXM frequency band.

Output 215 of matching circuit 214 may also be coupled to the input 222 of a filter 224; filter 224 may also have an output 226. Filter 224 may be a high-pass filter, designed to suitably pass the relatively-higher SXM frequencies and suitably reject, substantially reject or filter out the relatively-lower AM/FM frequencies. Filter 224 may be similar to or identical with filter 148, and similar design considerations may apply. Filter 218 may be a Butterworth filter, a relatively-simple filter that may be employed given the relatively-large separation between the AM/FM frequency bands and the satellite radio (e.g., SXM) frequency band.

In an alternative, an RF switch may be provided that couples output 212 of bias-tee circuit 206 alternately to receiver module 200 and receiver module 202.

The present disclosure is susceptible of embodiment in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, “any” and “all” shall both mean “any and all”, and the words “including”, “containing”, “comprising”, “having”, and the like shall mean “including without limitation”. Moreover, words of approximation such as “about”, “almost”, “substantially”, “generally”, “approximately”, etc., may be used herein in the sense of “at, near, or nearly at”, or “within 0-5% of”, or “within acceptable manufacturing tolerances”, or logical combinations thereof.

What is claimed is:

1. A radio system comprising:
a first source of first radio signals, the first radio signals being in a first frequency range, the first source including a first amplifier with a first amplifier output;
a second source of second radio signals, the second radio signals being in a second frequency range, the second frequency range distinct from the first frequency range, the second source including a second amplifier with a second amplifier output;
a first filter adapted to substantially reject the second frequency range, the first filter having a first filter input and a first filter output, the first filter input coupled to the first amplifier output;
a second filter adapted to substantially reject the first frequency range, the second filter having a second filter input and a second filter output, the second filter input coupled to the second amplifier output;
a first bias-tee circuit having a first direct current (“DC”) terminal, a first radiofrequency (“RF”) terminal, and a first DC+RF terminal, the first RF terminal coupled to the first filter output and to the second filter output;
a second bias-tee circuit having a second DC terminal, a second RF terminal, and a second DC+RF terminal;
a DC power supply coupled to supply power to the second DC terminal; and
a conductor coupling the first DC+RF terminal and the second DC+RF terminal, the conductor carrying the first radio signals for reception by a first receiver adapted to decode the first radio signals, the second radio signals for reception by a second receiver adapted to decode the second radio signals, and DC power from the DC power supply to power the first amplifier and the second amplifier.

2. The radio system of claim 1, wherein:
the first radio signals are amplitude modulated/frequency modulated (“AM/FM”) radio signals; and
the second radio signals are satellite radio signals.

3. The radio system of claim 1, wherein the first radio signals are FM radio signals.

4. The radio system of claim 1, further comprising:
a third filter having a third filter input and a third filter output; and
a fourth filter having a fourth filter input and a fourth filter output;
wherein
the third filter input is coupled to the second RF terminal;
the fourth filter input is coupled to the second RF terminal;
the third filter output is coupled to the first receiver; and
the fourth filter output is coupled to the second receiver.

5. The radio system of claim 4, further comprising a first L-C matching circuit disposed between the first filter output and the first RF terminal and between the second filter output and the first RF terminal.

6. The radio system of claim 5, further comprising a second L-C matching circuit disposed between the second RF terminal and the third filter input and between the second RF terminal and the fourth filter input.

7. The radio system of claim 1, wherein the first filter is a low-pass filter adapted to substantially reject the second frequency range.

8. The radio system of claim 7, wherein the first filter is a Butterworth filter.

9. The radio system of claim 7, wherein the second filter is a high-pass filter adapted to substantially reject the first frequency range.

10. The radio system of claim 1, further comprising a voltage splitter having:
a voltage splitter input coupled to receive power from the first DC terminal;
a first voltage splitter output coupled to provide DC power to the first amplifier; and
a second voltage splitter output coupled to provide DC power to the second amplifier;
wherein the first voltage splitter output has a voltage that is different than a voltage of the second voltage splitter output.

11. The radio system of claim 7, wherein the first filter comprises first electrical components and the second filter comprises second electrical components, at least some of the first electrical components having higher quality factors than at least some of the second electrical components.

12. The radio system of claim 11, wherein at least some of the first electrical components are in 0805, 0603, or 0402 packages.

13. The radio system of claim 4, wherein the third filter is a low-pass filter adapted to substantially reject the second frequency range.

14. The radio system of claim 13, wherein the fourth filter is a high-pass filter adapted to substantially reject the first frequency range.

15. The radio system of claim 1, wherein the conductor is a coaxial cable.

16. A vehicle having a radio system, the radio system comprising:
a first source of first radio signals, the first radio signals being in a first frequency range, the first source including a first amplifier with a first amplifier output;
a second source of second radio signals, the second radio signals being in a second frequency range, the second frequency range distinct from the first frequency range, the second source including a second amplifier with a second amplifier output;
a first filter adapted to substantially reject the second frequency range, the first filter having a first filter input and a first filter output, the first filter input coupled to the first amplifier output;
a second filter adapted to substantially reject the first frequency range, the second filter having a second filter input and a second filter output, the second filter input coupled to the second amplifier output;
a first bias-tee circuit having a first DC terminal, a first RF terminal, and a first DC+RF terminal, the first RF terminal coupled to the first filter output and to the second filter output;
a second bias-tee circuit having a second DC terminal, a second RF terminal, and a second DC+RF terminal;
a DC power supply coupled to supply power to the second DC terminal; and
a conductor coupling the first DC+RF terminal and the second DC+RF terminal, the conductor carrying the first radio signals for reception by a first receiver adapted to decode the first radio signals, the second radio signals for reception by a second receiver adapted to decode the second radio signals, and DC power from the DC power supply to power the first amplifier and the second amplifier.

17. The vehicle of claim 16, wherein the first radio signals are AM/FM radio signals.

18. The vehicle of claim 17, wherein the second radio signals are gigahertz radio signals.

19. The vehicle of claim 18, wherein the second radio signals are satellite radio signals.

20. A radio system comprising:
a first source of first radio signals, the first radio signals being in a first frequency range, the first source including a first amplifier with a first amplifier output;
a second source of second radio signals, the second radio signals being in a second frequency range, the second frequency range distinct from the first frequency range, the second source including a second amplifier with a second amplifier output;
a first filter adapted to substantially reject the second frequency range, the first filter having a first filter input and a first filter output, the first filter input coupled to the first amplifier output;
a second filter adapted to substantially reject the first frequency range, the second filter having a second filter input and a second filter output, the second filter input coupled to the second amplifier output;
a first bias-tee circuit having a first DC terminal, a first RF terminal, and a first DC+RF terminal, the first RF terminal coupled to the first filter output and to the second filter output;
a second bias-tee circuit having a second DC terminal, a second RF terminal, and a second DC+RF terminal;
a third filter having a third filter input and a third filter output and adapted to substantially reject the second frequency range, the third filter input coupled to the second RF terminal and the third filter output coupled to a first radio receiver adapted to decode the first radio signals;
a fourth filter having a fourth filter input and a fourth filter output and adapted to substantially reject the first frequency range, the fourth filter input coupled to the second RF terminal and the fourth filter output coupled to a second radio receiver adapted to decode the second radio signals;
a DC power supply coupled to supply DC power to the second DC terminal; and
a coaxial cable coupling the first DC+RF terminal and the second DC+RF terminal, the coaxial cable carrying the first radio signals for reception by a first receiver, the second radio signals for reception by a second receiver, and DC power from the DC power supply to power the first amplifier and the second amplifier.
